(19) United States
(12) Patent Application Publication
(10) Pub. No.: US 2026/0333883 A1
(43) Pub. Date: Oct. 22, 2026

(54) PHOTOVOLTAIC DEVICE WITH INTEGRATED ELECTRICAL LINES

(71) Applicant: Perovskia Solar AG, Aubonne (CH)

(72) Inventors: Anand VERMA, Aubonne (CH); Tobias MEYER, Féchy (CH); Jessica GIRARD, Saint-Sulpice (CH)

(73) Assignee: Perovskia Solar AG, Aubonne (CH)

(21) Appl. No.: 19/481,442

(22) PCT Filed: May 2, 2024
(86) PCT No.: PCT/IB2024/054238

§ 371 Date: Nov. 4, 2025

(30) Foreign Application Priority Data
May 12, 2023 (CH) 000507/2023

(51) Int. Cl. H10F 19/85; H10F 19/90

(52) U.S. Cl. CPC H10F 19/85; H10F 19/904

(57) ABSTRACT

A photovoltaic device comprising a photovoltaic cell with a light-harvesting surface and a back surface forming the back electrode, a top layer covering the light-harvesting surface of the photovoltaic cell and/or an encapsulation matrix material forming a protective film around solid elements of the photovoltaic cell, and a back layer covering the back surface of the photovoltaic cell. The top layer and/or the encapsulation matrix material together with the back layer encapsulate the photovoltaic cell. The back layer is provided with electrically conductive lines for electrically connecting to the electrodes of the photovoltaic cell. The invention also concerns a method for fabricating the photovoltaic device.

### TECHNICAL DOMAIN

The present invention concerns a photovoltaic device with integrated electrical connections.

### RELATED ART

Photovoltaic (PV) conversion technology has significantly progressed over the past decades. Today PV cells, in particular solar cells, provide an extremely attractive alternative to conventional energy sources due to their excellent mechanical robustness and high power conversion efficiency. Due to the advances in PV technology, PV cells are now used as power source in a broad variety of fields, from transportation and cladding for building structures to wearable devices, from telecommunication and satellites to advanced sensors, and many more.

In order to sustain their functionality, PV cells need to be protected from the environment, in particular from humidity, moisture and contamination. For this reason, PV cells, in particular rigid wafer-based PV cells, are conventionally sealed using cover plates, for example glass plates, between which the PV cell is layered such that it is protected from the top and the back, with circumferential sealing providing protection from the side.

Alternatively, photovoltaic cells may also be encapsulated, for example using polymer films or epoxy layers. This type of encapsulation is a preferred protection mechanism for flexible PV cells, for example thin film PV cells or flexible perovskite PV cells, as the encapsulation does not significantly affect the inherent flexibility of the PV cell. The reduced weight of this encapsulation material compared to conventional glass plate layers renders it also very suitable for rigid-wafer PV cells, in particular for lightweight PV cells which may be integrated in electronic devices, in smart grids, or in wearables.

It is known that PV device may be provided with electrically conductive lines or electrical circuits, which are generally provided as a separate electrically conductive layer, for example a printed circuit board (PCB).

WO2020201776 for example discloses a solar power module for a cladding member with polymeric encapsulation layers and an electrical junction configured to connect to the solar power module. The solar module may comprise an electrical connection layer, such as a PCB layer, between a functional solar power layer and a back plate providing the structural support of the solar power module. The electrical connection layer is sealed within the encapsulation layers of the solar power module. While the solar power module of WO2020201776 is suitable for a flat, rigid tiles, the disclosed module is complex as it requires a superposition of several encapsulation layers, a solar power layer as well as an electrical connection layer.

This complex arrangement is however less suited for small solar modules intended for integration into lightweight electronic devices. In addition, since the electrical connection layer is sealed within the encapsulation layers, it cannot be adjusted without removal of at least the back encapsulation plate. The encapsulated photovoltaic module of WO2020201776 is also not suitable for being retrofitted with an electrical connection layer or components thereof.

The present invention sets out to overcome the shortcomings and limitations of the state of the art.

### SHORT DISCLOSURE OF THE INVENTION

It is an aim of the present invention to provide a photovoltaic (PV) device with integrated electrical traces or a circuit in a simple and robust architecture. The PV device should preferably be easy to assemble.

It is another aim of the present invention to provide a photovoltaic (PV) device with integrated electrical traces or a circuit, which is readily customizable. The electrical traces or circuit of the assembled device should preferably be capable to be adapted according to specific requirements.

It is another aim of this invention that the PV device can be adapted to be mounted on flexible substrates as well as on rigid substrates. The PV device with integrated electrical traces or a circuit should be suitable for thin film applications.

It is yet another aim of this invention to provide a PV device with an integrated electrical traces or circuit in an alternative architecture to PV devices known in the art.

According to the present invention, one or more of these aims are attained by the object of the attached claims, and especially by the independent claims. The dependent claims concern advantageous embodiments of the independent claims.

In particular, one or more of these aims are attained by a PV device comprising a photovoltaic cell, preferably a solar cell, with a light-harvesting surface and a back surface comprising or constituting the back electrode and a top layer covering the light-harvesting surface of the PV cell and/or an encapsulation matrix material forming a protective film around solid elements or components of the PV cell. The PV device further comprises a back layer covering the back surface of the PV cell.

The top layer and/or the encapsulation matrix material together with the back layer surround the PV cell, protecting the PV cell and its components from the environment, in particular from humidity, from moisture and from contaminants. The encapsulation matrix material may be provided on top of the PV cell, at least partially diffused in the PV cell, and/or on the back of the PV cell. To provide adequate encapsulation of the PV cell, the PV device is provided with a back layer which protects the back side of the PV cell and is part of the encapsulation. The back layer may be adhered to a layer of encapsulation matrix material provided at the back side of the PV cell, such as to reinforce the encapsulation.

The encapsulating back layer provides the advantage that the durability of the PV device is significantly increased compared to PV devices which comprises an encapsulation without the back layer. Moreover, the back layer improves the overall robustness of the PV device.

The top layer and/or the encapsulation matrix material together with the back layer therefore provide an encapsulation of the PV cell. The encapsulation provides an environmental seal for the encapsulated PV cell and, optionally, additional layers provided with the PV cell.

The top layer, the encapsulation matrix material are preferably made of electrically non-conductive material.

In one embodiment the base material of the back layer is non-conductive. A non-conductive base material provides the advantage that the contact points between electrically conductive lines and the electrodes of the PV cell can be clearly defined.

The electrical contacts may for example be established via electrically conductive contact pads of the back layer. An electrical contact, such as a contact pad, may be formed by an aperture, for example a hole or a slot, in the back layer through which conductive material extends between the electrically conductive lines of the back layer and an electrode of the PV cell. Electrical contacts may for example be arranged in opposed peripheral portions of the back layer such as to contact the PV electrodes positioned at opposite ends of the PV cell.

The back layer is provided with electrically conductive lines which electrically connect to the electrodes of the PV cell. One electrode may for example be provided by the top layer, which may be a glass layer with a conductive oxide coating. The other electrode is provided by the back electrode of the PV cell.

The electrically conductive lines are preferably arranged as or comprised in an electrical circuit mounted on or embedded in the back layer. The electrically conductive lines may be printed onto the back layer, such that the encapsulating back layer is a PCB layer.

Electrically conductive lines, also referred to as traces, may be produced by procedures commonly known in the art, for by etching or by printing the lines on the back layer. The invention is not particularly limited to how the lines are produced on the encapsulating back layer.

The electrically conductive lines may be provided on the surface of the encapsulation layer which faces the PV cell. Alternatively, or additionally, the electrically conductive lines be provided on the opposing, i.e. the outward facing surface of the back layer.

This invention provides for an architecture of the PV device with integrated electrically conductive lines or traces, which can be kept very simple. A functional PV device with electrical circuit in its simplest embodiment may comprise the PV cell in its encapsulation, consisting of a top layer and/or an encapsulation matrix material and of an encapsulation back layer with electrically conductive lines, only.

The encapsulation matrix material may cover the light-harvesting surface of the PV cell, and/or diffuse into the PV cell to surround solid particles and/or members of the PV cell. The encapsulation matrix material provides protection by covering or surrounding solid particles and/or members of the PV cell.

A PCB back layer may be provided as a single layer. It is however also possible to provide a PCB back layer with a multi-layer architecture. In other words, the PCB back layer may comprise two or more sub-layers. Such sub-layers may serve different functionalities, such as improved conduction or heat dissipation. For example, microchannels may be included in a multilayered structure to allow for cooling or temperature control of the PV cells.

The sub-layers may also constitute components which are electrically connected to the conductive lines, such as sensors or connections to other electronic components or devices. Electronic components may therefore be integrated in the back layer of the PV device in the form of sub-layers to form a working circuit, or assembly in the PV device.

Alternatively, or additionally, electronic components may be mounted as external components on the back layer and connect to its electrically conductive lines traces.

Due to its very simple structure, the PV device can be easily adapted for different application. It can be provided as a very thin PV device, to render it suitable for thin film applications. It may for example be used for sensing devices, monitoring devices, or display devices.

The back layer may be at least partially flexible, such that the PV device is adapted to be used with flexible substrates or flexible external devices. However, the back layer may also be provided as a rigid back plate.

Its electrically conductive lines enable the PV device to be readily integrated into electronic equipment and/or to join different electrical components.

According to this invention the PV device may be assembled using a back layer comprising electrically conductive lines for encapsulation.

It is however also possible, that the back layer is provided with electrically conductive lines in the already assembled PV device.

Since the lines can be provided after the assembly and encapsulation of the PV device, the PV device can easily be retrofitted with these lines. Likewise, a non-conductive back layer without traces of an assembled PV device can be readily transformed into a PCB by retrospectively providing traces on the outwardly facing surface of the back layer and by establishing an electrical connection between said traces and the electrodes of the PV cell. Said electrical connection may for example be established by arranging an electrically conductive material between the electrically conductive lines of the back layer and the electrodes of the PV cell. The electrically conductive material may extend through a hole or conduit in the back layer to establish the contact with an electrode.

With respect to what is known in the art, the invention provides the advantage that the electrical traces can be added to an assembled PV device, the PV device can therefore be retrofitted with electrically conductive lines, or with a PCB.

Due to its encapsulating back layer with its electrically conductive lines the PV device of this invention achieves to combine great design freedom with improved robustness and durability. The back layer and its electronic lines and components can be adapted to specific PV cells and to external devices for which the PV device is designed. The PV device of this invention may for example be designed for thin film applications by providing a flexible PV cell and back layer.

Moreover, the electrical traces of the PV device of this invention can be readily modified by adding or removing electronic components to the electrically conductive lines, such as a resistor, a transistor, a capacitor, an inductor, a sensor, a transformer, an integrated circuit, a chip, a diode, and/or an electronic device, such as an IOT device, sensor device for sensing gas, temperature or humidity, a memory device, or a transmitter device, to adjust the functionality of the PV device. The modifications can be easily performed on the assembled device, as the electronically conductive lines are fixed on or embedded in the back layer. Therefore, the lines are not displaced, for example during mechanical distortion or mechanical bending of a flexible back layer, from their fixed position in the encapsulating back layer.

The encapsulating back layer with its electrically conductive lines is electrically connectable to other electric members, such as electric wires, functional elements, integrated circuits, processors, chips, or electronic units, such as sensors. Other electric members may be provided as external elements, components, or devices. Alternatively, or additionally, electrical members may also be comprised in the PV device, for example in form of sub-layers of a PCB back layer.

The PV device of this invention can therefore easily be adapted for integration in a broad variety of electric or electronic units or devices.

The PV device is particularly suited as a power source for lightweight applications, for example for flexible and/or portable electronics, wearables, such as for self-powered internet-of-things (IoT) systems, or for satellite applications.

In one embodiment of this invention, the PV device comprises a perovskite PV cell, an organic PV cell, a dye-sensitized PV cell, a quantum dot photovoltaic cell, or another type of thin film PV cell.

A suitable perovskite PV cell may for example be a cell as described in WO2022214848 comprising a polymer matrix material, which serves as an encapsulation matrix material.

The encapsulation matrix material is preferably a polymer of a mixture of polymers. The use of the encapsulation matrix material is not particularly limited to perovskite PV cells described in WO2022214848. It may also be applied as encapsulation material for other types of PV cells.

Suitable encapsulation matrix polymers of varied chain lengths include for example polystyrene (PS), polyethylene terephthalate (PET), polyolefin (PO), poly(vinyl alcohol) (PVA), or, preferably, poly(methyl methacrylate) (PMMA). The encapsulation matrix polymer may also be an ionomer, such as an ethylene methacrylic acid copolymer with zinc (Zn), sodium (Na), lithium (Li) or other metal ions. The encapsulation matrix polymer may be a combination of two or more different matrix polymers, ionomers. The encapsulation matrix polymer may comprise one or more small molecules.

The encapsulation matrix material may be provided as a layer. The encapsulation matrix material may also penetrate or diffuse into functional layers of the PV cell or, optionally, additional layers comprised between the top and the back layer.

A PV device according to this invention may comprise an encapsulation matrix material or an encapsulating top layer. A PV device according to this invention may also comprise both, an encapsulation matrix material and an encapsulation top layer.

The encapsulation matrix material may be provided as matrix for solid particles or materials of the layers of a PV cell.

The encapsulating top layer of the PV device may be made of one or more flexible polymers selected from a group consisting of polyimide, polyether imide, polyethylene naphthalene (PEN), PS, PET, and PO. The polymers may be provided in a variety of chain lengths.

The encapsulating back layer may be made of one or more polymers selected from a group consisting of PS, PET, PO, PVA, and PMMA. The polymers may be provided in a variety of chain lengths.

The encapsulating back layer may also be made of ionomers and/or other composite materials, and or any suitable PCB materials. Depending to requirements or preferences, the back layer may be made of flexible or rigid material. The invention is not particularly limited to any specific material. The material should however be electrically non-conductive.

The back layer may be adhered to the PV, the encapsulation matrix polymer and/or the top layer cell by an adhesive, such as an epoxy adhesive or another connective polymer material. The adhesive may comprise a mixture of adhesive materials, including polymers and/or ionomers.

The adhesive material may be provided in any suitable form including as a printable or coating ink, as a powder, or as a film.

The adhesive may for example be curable under UV irradiation. In this embodiment, it is advantageous if the back layer is UV transparent or UV translucent, such that the adhesive can be cured when the backside of the PV device is exposed to UV irradiation.

The electrical connection between the back electrode of the photovoltaic cell and the conductive lines of the back layer may be established in different ways.

The connection may for example be established by an electrically conductive adhesive, which may be a conductive glue or paste, or by an electrically conductive polymer film, for example an adhesive or a polymer film comprising a metal.

It is also possible that electronic connections between the electrically conductive lines and the electrodes of the PV cell are established with soldered connections.

As a further option, an electrically conductive material may be arranged between the electrical lines of the back layer and the electrodes such as to establish an electrical connection.

Different combinations of the above-mentioned options to connect the electrically conductive lines of the back layer to the electrodes are possible.

For embodiments in which the front electrode or particles thereof are surrounded by the encapsulating matrix material, the connection between the electrodes can be established through an aperture, for example a hole or a slot, in the encapsulating matrix material for connecting the electrically conductive lines with the back electrode. It is also possible to provide a connection between the electrodes with a lateral overlap of the conductive material, such as to electrically connect the conductive material of the back layer with the back electrode.

A PV device of the present invention may be assembled by providing a PV cell, wherein the PV cell may be provided with the encapsulation matrix material, which preferably protects one or more functional layers of the PV cell. If the PV cell comprises the encapsulation matrix material, the encapsulating top layer is not required, but may optionally be arranged on top of the PV cell. If on the other hand the PV cell does not comprise the encapsulation matrix material, the encapsulating top layer must be arranged on the light-harvesting surface of the PV cell.

The back layer is then arranged on the back surface of the PV cell, such that the top layer and/or the encapsulation matrix material together with the back layer completely surround(s) the photovoltaic cell.

The back layer may optionally comprise electrically conductive lines when arranged on the back surface of the PV cell. As described above, it is however also possible to arrange a back layer without electrically conductive lines on the PV cell and to add the electronically conductive lines afterwards.

The back layer is then adhered, such that the top layer and/or the encapsulation matrix material together with the back layer encapsulate the photovoltaic cell. For this purpose, the back layer may be adhered directly to the back surface of the PV cell.

Alternatively, or additionally, the back layer may be adhered to the encapsulating matrix polymer and/or the top layer.

The back layer is adhered in such a way that it forms an environmental seal together with the top layer and/or the encapsulation matrix material.

Optionally, if the adhered back encapsulation layer does not comprise conductive lines, etching and/or printing conductive lines into or onto the back encapsulation layer adhered to the photovoltaic cell.

A conductive connection between said lines of the back layer and the electrodes of the photovoltaic cell is established. Different options for establishing these connections are described above.

The back layer may for example be adhered to the PV cell using an epoxy adhesive. The epoxy adhesive may be cured thermally, chemically or by irradiation, for example in the UV, visible, or IR light wave range, to the epoxy adhesive.

Since a large portion of UV light generally passes through the light harvesting layers of a PV cell, the epoxy adhesive between the back layer and the PV cell may be cured by applying UV light, or light comprising UV wavelength, to the light-harvesting side of the PV device.

PV cells are generally designed to absorb light in the visible spectrum. However, they can also absorb some light in the ultraviolet range.

In order to improve the UV-induced curing of the adhesive material, it is therefore advantageous if the back layer is made from a UV translucent or a UV transparent material. In this embodiment the adhesive may be irradiated with UV light from the back side, i.e. the opposite the light-harvesting surface of the PV cell.

### SHORT DESCRIPTION OF THE DRAWINGS

Exemplar embodiments of the invention are disclosed in the description and illustrated by the drawings in which:

FIG. 1 illustrates schematically an embodiment of a PV device according to this invention in a perspective view;

FIG. 2a is a schematic illustration of a side view of a possible embodiment PV device comprising an encapsulating top layer as well as an encapsulating matrix material and an encapsulating back layer;

FIG. 2b is a detailed view of the illustration shown in FIG. 2a;

FIG. 3 is a schematic illustration of a side view of a possible embodiment PV device comprising a perovskite PV cell with an encapsulation matrix polymer which is at least partially diffused over the functional layers of the PV cell and an encapsulating back layer.

### EXAMPLES OF EMBODIMENTS OF THE PRESENT INVENTION

The invention is illustrated by the following non-limiting examples.

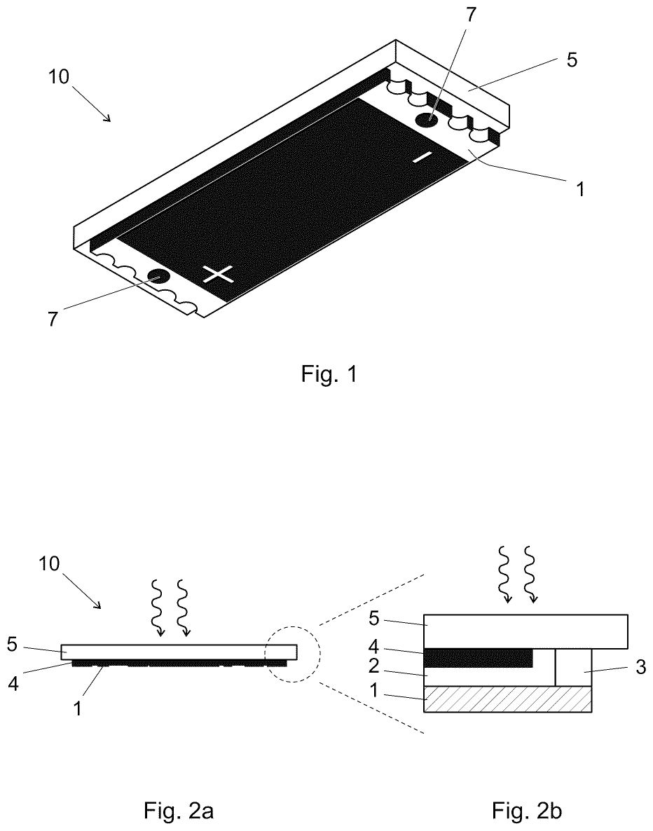

A perspective view of a first embodiment according to this invention is shown in FIG. 1 and a schematic illustration of the same type of PV device 10 are depicted in FIGS. 2a and 2b. FIGS. 2a and 2b are schematic illustrations and not to scale.

The PV device 10 shown in these figures comprises a top layer 5, through which visible light, indicated as wavy arrows, passes to reach the underlying PV cell 4. The top layer 5 of the embodiment shown here is a rigid layer made of glass or similar material which is transparent or translucent for light in the visible range.

The top layer may be coated with layer with a conductive oxide to provide the front electrode of the PV device 10.

The PV cell 4 may optionally be adhered to the glass plate. An adhesive may be provided in any suitable form, as a film, a powder, or printed ink.

The PV device 10 further comprises an encapsulation matrix material 2, which covers at least the back surface of the PV cell 4, which is the surface opposite the light harvesting surface.

Alternatively, or additionally, the encapsulation matrix material may at least partially cover or diffuse the PV cell 4 such as to surround and thereby encapsulate solid members and particles of the PV cell 4, respectively its layers. The encapsulation matrix material is preferably a non-conductive polymer, an ionomer, or a small molecule, which does not significantly interfere with the functionality, in particular the electron or hole transport, of the PV cell.

Suitable polymers for the encapsulation matrix material, which can cover and/or diffuse into functional layers of PV cells without causing significant interference are PS, PET, PO, PVA, PMMA, which may each be provided in various chain length, as well as ionomers and/or small-molecules.

The PV cell 4 with its top layer 5 and the encapsulation matrix material 2 are disposed on the back layer 1 which is connected, for example soldered, to the top layer with conductive ink or solder 3, such that an electrical connection is established between the electrically conductive lines of the back layer 1 and the front electrode provided by the top layer 5.

Similarly, the electrical connection between the back electrode, which is constituted by the back surface of the PV cell 4, and the conductive lines of the back layer 1 may be provided with a further connection through conductive ink or solder.

In one embodiment the back surface of the PV cell 4 is conductively connected to an end portion of the top layer 5 projecting from the PV cell 4 as shown in FIG. 2a such that this portion of the top layer carries the electric charge of the back electrode. In this embodiment the positive electrode and the negative electrode are provided on the top layer and are separated by an insulator line.

The positive and negative electrodes are preferably arranged laterally from the active layers of the PV cell 4, for example in the projecting portions of the top layer 5.

As shown in FIG. 1, the electrical contacts between the conductive lines of the back layer 5 and laterally arranged electrodes may be provided by contact pads 7, which establish the electrical connection between the positive and negative electrodes and the conductive lines of the back layer 5.

For this purpose, single cell serial interconnections may be provided in the non-conductive material 2 disposed between the electrically conductive lines and the PV cell 4. It is also possible to provide inert conducting material on the back surface of the PV cell which electrically connects to the conductive lines of the back layer 1. One or more apertures, such as a hole, a cut, or a slot, may be provided for a conductive adhesive or solder to establish an electrical connection.

The back layer 1 is connected to the encapsulation matrix material and to the top layer 5 such as to form an environmental seal, which protects the PV cell 4 layered between the top layer 5 and the back layer 1.

The electrically conductive lines may be embedded in, mounted on, or printed on either of the surfaces of the back layer 1.

In the example shown, the conductive lines are provided on the surface of the back layer 1, which faces the PV cell 4. It is however also possible to provide the electrically conductive lines on the other surface of the back layer 1.

The back layer 1 may be formed of flexible, partially flexible or a rigid material. In the example shown in FIGS. 1 to 2B a rigid glass plate is provided as a top layer 5, and the flexibility or rigidity of the back layer 1 does therefore not affect the flexibility of the overall PV device 10. Suitable flexible materials for the back layer 1 are PS, PET, PO, PVA, PMMA, and any flexible PCB material.

However, for flexible PV devices with a flexible back layer 1, the top layer 5 may also be formed of suitable flexible materials, such as polyimide, polyether imide, PEN, PS, PET, and PO.

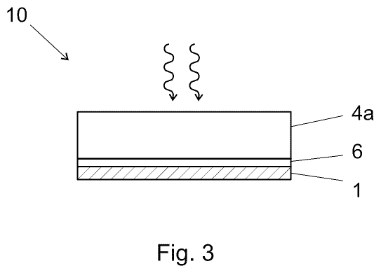

FIG. 3 depicts a second embodiment of a PV device 10 according to the present invention. This figure is executed schematically and not to scale.

The depicted device 10 comprises a perovskite PV cell 4a with an encapsulating matrix polymer which is diffused in at least one or more of the upper functional layers of the PV cell 4a. A suitable type of perovskite PV cell with polymer matrix is described in greater detail in WO2022214848.

The perovskite PV cell 4a described in WO2022214848 comprises a functional perovskite layer, the first layer, disposed on and partially diffusing into its underlying functional layer. The latter comprise a second layer comprising at least one metal oxide insulating material, such as ZrO₂, preferably mesoporous ZrO₂, Al₂O₃ and/or SiO₂, which is disposed on third layer comprising at least one metal oxide semiconductor, preferably a colourless semiconductor, such as TiO₂, preferably having a band gap equal to or greater than 2.7 eV, or equal to or greater than 3 eV. The composition forming the perovskite layer may comprise conductive particles, which are suitable to function as electrode material. Alternatively, or additionally, an electrode layer comprising conductive particles may be disposed on top of the perovskite layer. If a top layer 5 is provided with the perovskite cell, this top layer is disposed on the opposite side of the electrode layer, i.e., on the side of the third functional layer.

Different from the perovskite composition or layer and the encapsulating matrix polymer, the conductive particles do not diffuse into the underlying layers during the fabrication of the PV cell. Instead, the conductive particles are contained in a layer, which functions as back electrode. The conductive particles are contained in this layer regardless of whether they are disposed onto the PV device as part of the perovskite composition or as part of a separate electrode composition.

The encapsulating matrix material, which is preferably a matrix polymer, may be applied as a layer on top of the perovskite layer. Preferably the matrix material diffuses into its underlying layers, in particular the perovskite containing layer. Alternatively, the encapsulating matrix material may already be provided with a perovskite composition which is deposited unto its underlying functional layers during the fabrication of the PV cell.

The function of the encapsulation matrix material enhances performance and durability of the perovskite PV cell 4a. It also stabilizes the composition and structure of the PV device. The encapsulation matrix polymer forms a protective film around the solid particles and material, including the perovskite crystals, without significantly interfering with electron or hole transport. The encapsulation matrix material if selected with insulating property, it has a passivating and/or encapsulating effect on the material it surrounds. The polymer therefore provides protection for the components it covers without substantially interfering with their function. As a result, the polymer enhances the durability and robustness of the PV device without interfering with its performance. Moreover, the polymer or small molecules can be functionalized to enhance charge transport like electron conducting or hole-conducting.

The back surface of the perovskite PV cell 4a, which forms the back electrode of the PV cell 4a, is adhered to an encapsulating back layer 1 with electrically conductive lines, for example a PCB, which together with the encapsulating matrix material provides an environmental seal.

The back layer 1 may be adhered to the perovskite PV cell with an adhesive layer 6, which may be provided in different forms, such as glues, pastes, a thin film, or a powder. The adhesive layer 6 may be a conductive adhesive layer, to establish the electrical contact between the conductive lines of the back layer 1 and the back electrode of the perovskite PV cell 4a.

Alternatively, if the adhesive layer is electrically non-conductive, the electric connection between the conductive lines of the back layer 1 and the back electrode of the PV cell 4a may be established through an aperture, for example a hole or a slot, in the adhesive layer for connecting the electrically conductive lines with the back electrode.

A perovskite PV cell 4a as described above is suitable for thin film applications.

For applications requiring a flexible PV device a flexible back layer 1 should be adhered to the perovskite PV cell 4a.

The assembly of the perovskite PV device schematically illustrated in FIG. 3 is very straightforward. The PV cell 4a comprising the encapsulating polymer matrix can simply be glued to the back layer 1 with the electrically conductive lines or the circuit by a suitable adhesive or a suitable film 6. The adhesive may be cured thermally, chemically or curing the epoxy adhesive by applying irradiation, for example UV irradiation. Irradiation for curing of the adhesive may be provided from the light harvesting side of the PV device 10 or, provided the back layer is-transparent or translucent to the chosen radiation, from the back side of the PV device 10.

The adhesive may for example be an epoxy adhesive, silicon, rubber, and other encapsulation material. Epoxy adhesives have been shown to be particularly suitable for adhering the back layer 1 to the back electrode layer of the perovskite PV cell 4a. Advantageously, this adhesive does not interfere with the functioning of the perovskite PV cell. It also provides the freedom to be applied in different shapes and sizes.

While a specific type of perovskite PV cell has been described in greater detail herein, the PV device of this invention is not limited to this type of PV cells.

The embodiments shown in the Figures are also suitable for other types of single junction PV cells and multi-junction solar cells, for example organic photovoltaic cell, a quantum dot photovoltaic cell, a dye-sensitized photovoltaic cell, and tandem-solar cells, such as organic-perovskite, perovskite-perovskite, or other thin film photovoltaic cell.

The top layer 5, encapsulation matrix material, back layer 1 and adhesives mentioned or described herein, and different combinations thereof, may be used in combination with other types of PV cells.

Conditional language used herein, such as, among others, “can”, “might,” “may,” and the like, unless specifically stated otherwise, or otherwise understood within the context as used, is generally intended to convey that certain embodiments include, while other embodiments do not include, certain features, elements or states.

The terms “comprising”, “including”, “having”, and the like are synonymous and are used inclusively, in an open-ended fashion, and do not exclude additional elements, components, members, and so forth.

1. A photovoltaic device comprising
a photovoltaic cell with a light-harvesting surface and a back surface forming the back electrode,
a top layer covering the light-harvesting surface of the photovoltaic cell and/or an encapsulation matrix material forming a protective film around solid elements of the photovoltaic cell,
and a back layer covering the back surface of the photovoltaic cell,
wherein the top layer and/or the encapsulation matrix material together with the back layer encapsulate the photovoltaic cell, and
wherein the back layer is provided with electrically conductive lines for electrically connecting to the electrodes of the photovoltaic cell.

2. The photovoltaic device of claim 1, wherein the photovoltaic cell a perovskite photovoltaic cell, an organic photovoltaic cell, a dye-sensitized photovoltaic cell, quantum dot photovoltaic cell, or other thin film photovoltaic cell.

3. The photovoltaic device of claim 1, wherein the back layer is formed of a non-conductive base material.

4. The photovoltaic device of claim 1, wherein the back layer is a printed circuit board (PCB).

5. The photovoltaic device of claim 1, wherein the polymer matrix material comprises one or more polymers or ionomers selected from a group consisting of a polystyrene (PS), a polyethylene terephthalate (PET), a polyolefin (PO), a poly(vinyl alcohol) (PVA), a poly(methyl methacrylate) (PMMA), and an ethylene methacrylic acid copolymer with a metal ion.

6. The photovoltaic device of claim 1, wherein the back layer (1) is made of one or more polymers or ionomers selected from a group consisting of polystyrene (PS), polyethylene terephthalate (PET), polyolefin (PO), poly(vinyl alcohol) (PVA), and poly(methyl methacrylate) (PMMA), and an ethylene methacrylic acid copolymer with a metal ion.

7. The photovoltaic device of claim 1, wherein the back layer and the polymer matrix material are formed of the same polymer or ionomer.

8. The photovoltaic device of claim 1, wherein the back layer is at least partially flexible.

9. The photovoltaic device of claim 1, wherein the back layer is adhered to the photovoltaic cell by an adhesive, such as an epoxy adhesive or a mixture comprising an epoxy adhesive, polymer particles, or a polymer film.

10. The photovoltaic device of claim 9, wherein the electrical connection between the electrodes of the photovoltaic cell and the conductive lines of the back layer is established
by an electrically conductive adhesive or by an electrically conductive polymer film, for example an adhesive or by a polymer film comprising a metal,
by soldered connections, and/or
by a conductive material arranged to establish said electrical connection.

11. The photovoltaic device of claim 1, wherein the conductive lines of the back encapsulation layer connect one or more further electric and/or electronic components provided with the PV device, such as a resistor, a transistor, a capacitor, an inductor, a transformer, an integrated circuit, a chip, a diode, a sensor, and/or an electronic device, such as an Internet-of-Things (IoT) device, a transmitter device, or a memory device.

12. The photovoltaic device of claim 1, wherein the back layer comprises multiple sub-layers, at least one of said sub-layers comprising electronic components, such as sensing or monitoring components, which electrically connect to the electrically conductive lines of the back layer.

13. A method for fabricating the photovoltaic device of claim 1, comprising
(i) providing a photovoltaic cell with a light harvesting surface and a back surface, provided with a top layer on the light-harvesting surface of the photovoltaic cell and/or an encapsulation matrix material,
(ii) arranging a back layer, which optionally comprises electrically conductive lines, on the back surface of the photovoltaic cell,
(iii) adhering the back layer, such that the top layer and/or the encapsulation matrix material together with the back layer encapsulate the photovoltaic cell,
(iv) optionally, if the adhered back layer does not comprise conductive lines, etching and/or printing conductive lines into or onto the adhered back layer, and
(v) electrically connecting said conductive lines to the electrodes of the photovoltaic cell.

14. The method of claim 13, wherein the electric connection between the back electrode of the photovoltaic cell and the conductive lines of the back layer is established by soldering at least one conductive line to the electrically conductive back surface of the photovoltaic cell.

15. The method of any of claim 13, comprising adhering the back layer to the photovoltaic cell by applying an epoxy adhesive or another connective polymer material, between at least the electrically conductive back surface of the photovoltaic cell and the back layer.

16. The method of claim 13, wherein the back layer is adhered to the photovoltaic cell with an epoxy adhesive and wherein the method comprises curing the epoxy adhesive thermally, chemically or curing the epoxy adhesive by applying irradiation to the epoxy adhesive.

17. The method of claim 15, wherein the back layer is transparent or translucent to radiation, and wherein the epoxy adhesive is cured by irradiating the adhesive through the transparent or-translucent back layer of the photovoltaic device.

18. An electric or electronic device comprising at least one power device which is the photovoltaic device of claim 1.

19. The photovoltaic device of claim 1, wherein the top layer is coated with a conductive oxide to provide a front electrode of the photovoltaic device.

20. The photovoltaic device of claim 1, wherein the back electrode is provided by the back surface of the photovoltaic cell, and wherein an electrical connection between the back electrode and the conductive lines of the back layer is provided by a conductive ink or solder.

21. The photovoltaic device of claim 1, wherein an electrical connection between the back layer and the top layer is provided by a conductive ink or solder, such that an electrical connection is established between the electrically conductive lines of the back layer and the front electrode provided by the top layer.

22. The photovoltaic device of claim 1, wherein an end portion of the top layer projecting from the photovoltaic cell is conductively connected to the back surface of the photovoltaic cell forming the back electrode such that said end portion of the top layer carries the electric charge of the back electrode and the electric charge of the front electrode.
